(19) United States
(12) Patent Application Publication
(10) Pub. No.: US 2010/0090371 A1
(43) Pub. Date: Apr. 15, 2010

(54) Method of patterning conductive layers, method of manufacturing polarizers, and polarizers manufactured using the same

(76) Inventors: Deok Joo Kim, Daejeon Metropolitan City (KR); Sang Choll Han, Daejeon Metropolitan City (KR); Jong Hun Kim, Daejeon Metropolitan City (KR)

Correspondence Address: MCKENNA LONG & ALDRIDGE LLP, 1900 K STREET, NW, WASHINGTON, DC, 20006, US

(21) Appl. No.: 12/654,117

(22) Filed: Dec. 10, 2009

Related U.S. Application Data
(62) Division of application No. 11/450,344, filed on Jun. 12, 2006.

(30) Foreign Application Priority Data
Jun. 13, 2005 (KR) 10-2005-0050416
Jan. 10, 2006 (KR) 10-2006-0002763

(51) Int. Cl. B29C 59/02; G02B 1/10; C23C 14/34

(52) U.S. Cl. 264/293; 427/163.1; 204/192.1

(57) ABSTRACT

Disclosed is a method of patterning a conductive layer, a method of manufacturing a polarizer using the method and a polarizer manufactured using the same, and a display device having the polarizer. The method of patterning the conductive layer includes (a) patterning a resin layer to form grooves and protrusions, and (b) applying a conductive filling material on the resin layer so as to form a pattern using stereoscopic shapes of the grooves and the protrusions on the patterned resin layer.

### TECHNICAL FIELD

The present invention relates to a method of patterning a conductive layer, a method of manufacturing a polarizer, and a polarizer manufactured using the same.

This application claims the benefit of the filing date of Korean Patent Application Nos. 10-2005-0050416, filed on Jun. 13, 2005, and Korean Patent Application Nos. 10-2006-0002769, filed on Jan. 10, 2006 in the Korean Intellectual Property Office, the disclosure of which is incorporated herein in its entirety by reference.

### BACKGROUND ART

A polarizer is an optical element that draws linearly polarized light having a specified vibration direction from nonpolarized light, such as natural light. The polarizer is applied to extensive fields, such as sunglasses, filters for cameras, sports goggles, headlights for automobiles, and polarizing films for microscopes. Recently, application of the polarizer to liquid crystal displays has been increased.

In FIG. 1, a nanogrid polarizer as an example of the polarizer generates polarization using, a conductive nanogrid. However, it is impossible to apply a conventional nanogrid polarizer to a liquid crystal display because of a complicated manufacture process, low efficiency, and a difficulty in manufacturing the polarizer having a large area.

In detail, the conventional nanogrid polarizer is typically manufactured using the following two methods.

One method is illustrated in FIG. 3. According to this method, a conductive metal layer is formed on an inorganic substrate, such as glass or quartz, and a photoresist layer is formed on the conductive metal layer. Next, the photoresist layer is selectively exposed using a photomask and developed so as to be patterned. Subsequently, the conductive metal layer, which is layered under the photoresist layer, is etched using the patterned photoresist layer to pattern the conductive metal layer. Subsequently, the photoresist layer is removed.

Another method is shown in FIG. 4. According to this method, a conductive metal layer is formed on an inorganic substrate, and a photoresist layer is formed on the conductive metal layer. Next, the photoresist layer is pressed using a stamper so as to be deformed, exposed and developed to be patterned. Subsequently, the conductive metal layer, which is layered under the photoresist layer is etched using the patterned photoresist layer to pattern the conductive metal layer, and the photoresist layer is then removed.

As described above, the conventional method of manufacturing the nanogrid polarizer is problematic in that formation of the photoresist layer on the conductive metal layer, patterning of the photoresist layer, and the removal of the photoresist layer must be conducted to pattern the conductive metal layer, thus, a process is complicated and manufacture cost is high. Furthermore, since the photomask or the stamper that is used in the conventional method is manufactured using an electronic beam or X-rays, there is no alternative but to manufacture the polarizer having the small area. Accordingly, it is impossible to manufacture the nanogrid polarizer having the large area using conventional methods.

### DISCLOSURE

### Technical Problem

The present inventors established that, instead of a conventional etching process, when a resin is patterned to form grooves and protrusions using a plastic molding process, such as a heat molding or photocuring process and a conductive filling material is applied on the resin layer so as to form a pattern using stereoscopic shapes of the grooves and the protrusions, it is possible to prevent pollution caused by the etching process and squander of the conductive raw material and to pattern the conductive layer through a simple process at low cost. The present inventors also established that, when the stamper, which is manufactured through a stereolithographic process, is used to form the grooves and the protrusions on the resin, the conductive layer can be efficiently patterned with respect to the large area, thereby it is possible to manufacture the nanogrid polarizer having the large area.

Accordingly, an object of the present invention is to provide a method of patterning a conductive layer, a method of manufacturing a polarizer using the method, a polarizer manufactured using the same, and a display device having the polarizer.

### Technical Solution

An embodiment of the present invention provides a method of patterning a conductive layer, comprising (a) patterning a resin layer to form grooves and protrusions, and (b) applying a conductive filling material on the resin layer so as to form a pattern using stereoscopic shapes of the grooves and the protrusions on the patterned resin layer.

Another embodiment of the present invention provides a method of manufacturing a polarizer, comprising (a) patterning a resin layer to form grooves and protrusions, and (b) applying a conductive filling material on the resin layer so as to form a pattern using stereoscopic shapes of the grooves and the protrusions on the patterned resin layer.

Another embodiment of the present invention provides a polarizer including a resin layer that is patterned to form grooves and protrusions, and a conductive filling material that is applied so as to form a pattern using stereoscopic shapes of the grooves and the protrusions on the resin layer.

Another embodiment of the present invention provides a display device having the polarizer.

### DESCRIPTION OF DRAWINGS

The above and other features and advantages of the present invention will become more apparent by describing in detail, preferred embodiments thereof, with reference to the attached drawings in which:

FIG. 1 schematically illustrates a mechanism for operation of a nanogrid polarizer;

FIG. 2 is a sectional view of a conventional nanogrid polarizer;

FIG. 3 illustrates the manufacture of the conventional nanogrid polarizer using photomask exposing and etching processes;

FIG. 4 illustrates the manufacture of the conventional nanogrid polarizer using nanoimprinting and etching processes;

FIG. 5 illustrates the manufacture of a nanogrid polarizer according to an embodiment of the present invention;

FIG. 6 illustrates the manufacture of a nanogrid polarizer according to another embodiment of the present invention;

FIG. 7 illustrates the manufacture of a stamper using a stereolithography process;

FIGS. 8 to 12 are sectional views showing structures of nanogrid polarizers according to the present invention; and

FIG. 13 illustrates selective filling of a conductive filling material.

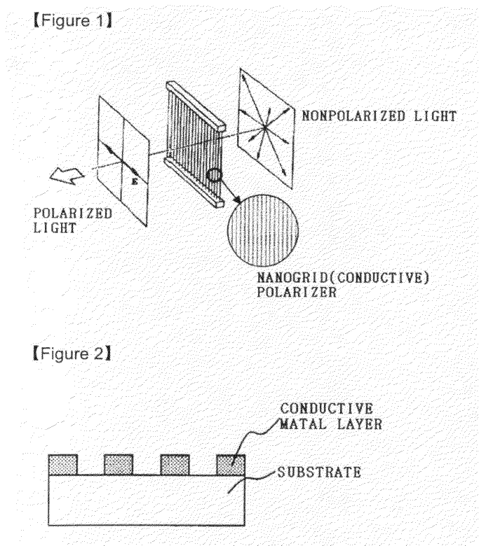

### BEST MODE

Hereinafter, a detailed description of the present invention will be given.

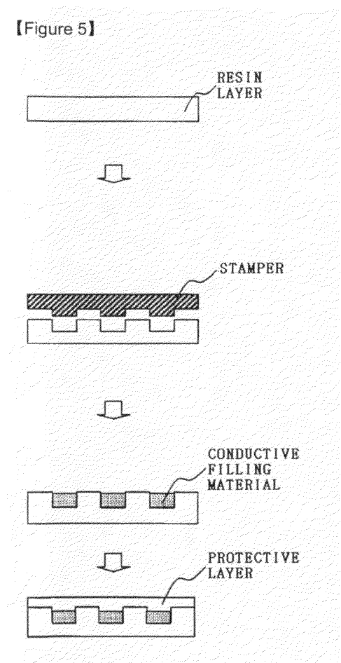

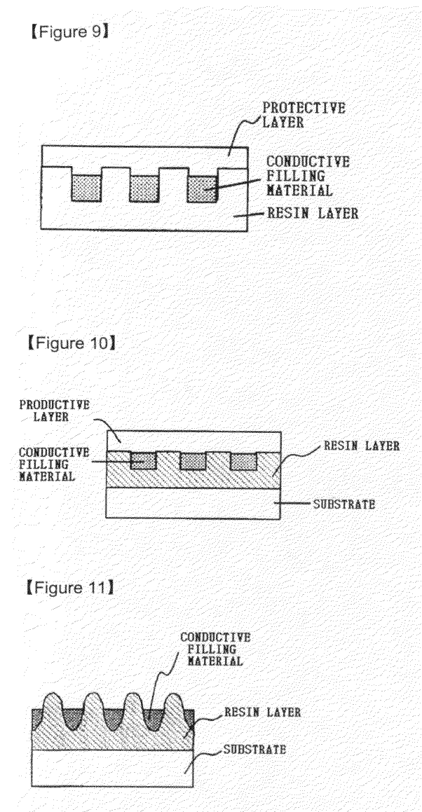

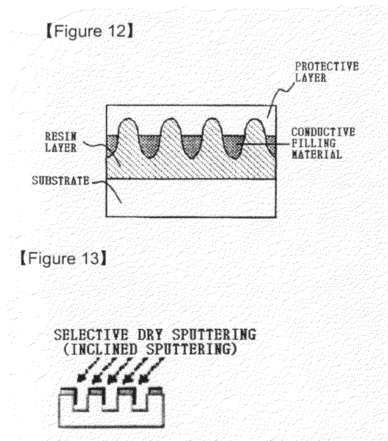

A method of patterning a conductive layer according to an embodiment of the present invention is shown in FIG. 5. In this embodiment, a resin layer, which is capable of serving as a supporter and on which a pattern of grooves and protrusions is capable of being formed is used. The resin layer is patterned to form the grooves and the protrusions. In this connection, the patterning of the grooves and the protrusions may be conducted, for example, in such a way that the resin layer is pressed using a stamper, and heat cured or photocured, and the stamper is then separated from the resin layer. In case a nanogrid polarizer is manufactured using the method of patterning the conductive layer according to the present invention, it is preferable that the grooves be arranged in a grid form at predetermined intervals. For example, the grooves and the protrusions on the resin layer may have shapes shown in FIGS. 8 to 10 or FIGS. 11 and 12. The shape is not limited as long as portions having the same shape are arranged at regular intervals. Furthermore, it is preferable that the grooves have the width and depth of decades to hundreds of nanometers to form the nanogrid.

Subsequently, a conductive filling material is applied on the resin layer so as to form a pattern using the stereoscopic shapes of the grooves and the protrusions of the resin layer. In this connection, the application of the conductive filling material on the resin layer so as to form the pattern using the stereoscopic shapes of the grooves and the protrusions does not mean a simple application method, but means that the conductive filling material is selectively applied on only a specific portion of a surface of the resin layer, for example only the grooves of the resin layer, only the protrusions of the resin layer, or a portion of the grooves and a portion of the protrusions, using the stereoscopic shapes of the grooves and the protrusions to form a patterned layer made of the conductive filling material.

Examples of a process of applying the conductive filling material include, but are not limited to, a selective wet coating process, such as knife coating, roll coating, and slot die coating processes, or a selective dry coating process, such as a deposition process including PVD (Physical Vapor Deposition) and inclined sputtering. The sputtering is a process where a sputtering gas is injected into a vacuum chamber and collides with a target material for forming a layer to generate a plasma, and the target material is applied on a substrate. The inclined sputtering is conducted in such a way that the gas is applied with an incline.

For example, as shown in FIG. 13, by using the inclined sputtering process, it is possible to selectively apply the conductive filling material on a portion of walls of the grooves and a portion of surfaces of the protrusions of the resin layer, thereby patterning the conductive layer.

In the present invention, as described above, the conductive filling material is directly applied on the resin layer so as to form a pattern using the stereoscopic shapes of the grooves and the protrusions of the resin layer. Hence, it is unnecessary to selectively remove the conductive filling material to conduct patterning with respect to the conductive filling material, thus the process can be simplified.

If necessary, after the conductive filling material is applied on the resin layer so as to form the pattern, a protective film may be formed thereon.

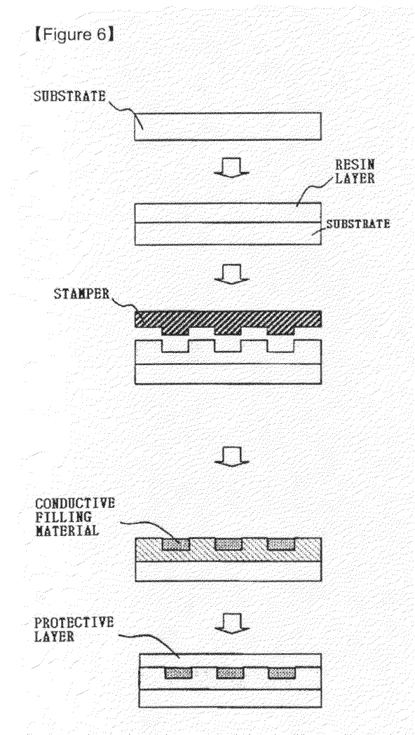

A method of patterning the conductive layer according to another embodiment of the present invention is illustrated in FIG. 6. In this embodiment, a resin layer curable by heat or light is formed on a substrate serving as a supporter. Subsequently, the curable resin layer is patterned to form grooves and protrusions. In this embodiment, the patterning of the grooves and the protrusions, application of a conductive filling material, and formation of a protective film are as described in the embodiment of FIG. 5.

In the present invention, a material of the resin layer, which is capable of being used without a separate supporter may be organic materials, such as plastics, for example, optically transparent organic materials, and such as polyester, polyethersulfone, polycarbonate, polyesternaphthenate, and polyacrylate. Since the above-mentioned material is capable of serving as the supporter and a molding resin, if the resin layer made of the above-mentioned material is used, a separate substrate may not be used.

In the present invention, a photocurable resin on which a micropattern is capable of being formed using a photocuring process may be used as a material of the resin layer which is formed on a substrate serving as a supporter, and the material may be exemplified by a transparent liquid resin, such as urethane acrylate, epoxy acrylate, and polyester acrylate. Since the above-mentioned transparent liquid resin has low viscosity, the liquid resin easily fills a mold frame of a stamper having a nano-sized mold to easily mold a nano-sized body. Furthermore, there are advantages in that attachment to the substrate is excellent and separation from the stamper is easy after the curing. In case the above-mentioned resin layer is formed on the substrate, an inorganic substrate, such as glass or quartz, or an optically transparent organic material may be used as the substrate. In the conventional method of patterning the conductive layer, since the inorganic substrate, such as glass or quartz, is used as the substrate, there is a problem in that the manufactured device has poor flexibility. However, in the present invention, the flexible organic material as well as the inorganic material may be used as the material of the substrate. Accordingly, the conventional method is suitable to a batch type process, but the present invention uses an organic substrate, such as a plastic film, thus being applied to a continuous process.

In the present invention, the conductive filling material functions to provide electrical conductivity to a target device. In particular, when the method of the present invention is used to manufacture the nanogrid polarizer, the conductive filling material may provide electrical conductivity to a nanogrid portion to realize functions of the polarizer. In the present invention, the conductive filling material may be exemplified by one or more conductive metals, such as silver, copper, chromium, platinum, gold, nickel, and aluminum, a mixture of organic materials therewith, or a conductive organic substance, such as polyacetylene, polyaniline, and polyethylenedioxythiophene. The conventional technology is problematic in that, since the metal thin film layer is used to form the conductive layer, flexibility of the material is poor. However, in the present invention, the above-mentioned desirable material is used to improve flexibility of the device. It is preferable that the particle size of conductive metal particles be several to decades of nanometers to selectively coat a specific portion of the resin layer using the stereoscopic shapes of the grooves and the protrusions of the nanogrid shape. Additionally, examples of the organic material, which is mixed with the conductive metal powder include, but are not limited to epoxy acrylate.

If necessary, in the present invention, after the conductive filling material is selectively applied on the resin layer using the stereoscopic shapes of the grooves and the protrusions of the resin layer, a protective film may be formed on the conductive filling material. The protective layer may be made of the material, such as epoxy acrylate, and formed using a coating process. If necessary, attachment, antistatic, and wear-resistant functions may be additionally provided to the protective layer.

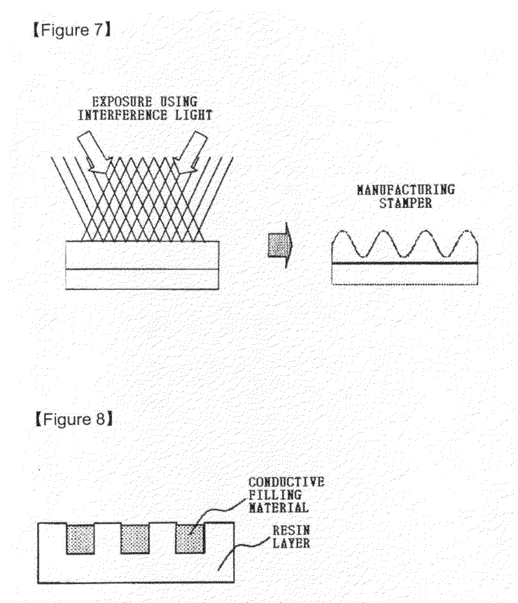

In the present invention, as described above, the process of patterning the resin layer to form the grooves and the protrusions may be conducted using a stamper. In particular, in the present invention, it is preferable to use the stamper, which is manufactured so as to have the large area using a stereolithography process. The term “stereolithography” denotes a process where a thin film of a photocurable composition is cured using a laser controlled by computers to manufacture a stereoscopic body. This process is disclosed in detail in U.S. Pat. Nos. 4,575,330, 4,801,477, 4,929,402, and 4,752,498, and Korean Unexamined Patent Application Publication Nos. 1992-11695 and 1998-63937. In the present invention, since the stereolithography process is used to manufacture the stamper applied to the method of patterning the conductive layer according to the present invention, it is possible to manufacture a stamper having a nano-sized mold and a large area, and thus the conductive layer can be efficiently patterned with respect to the large area. Furthermore, it is possible to manufacture the nanogrid polarizer having the large area using the above-mentioned process. In the present invention, the material of the mold of the stamper may be exemplified by metal, such as nickel, chromium, and rhodium, or an organic material, such as epoxy and silicone. FIG. 7 illustrates the manufacture of the stamper using the stereolithography process.

### [Mode for Invention]

A better understanding of the present invention may be obtained in light of the following examples which are set forth to illustrate, but are not to be construed to limit the present invention.

### Example 1

A polarizer was manufactured according to the procedure shown in FIG. 5. Specifically, a nickel stamper was manufactured using a laser stereolithography process so that the pitch was 200 nanometers and the line width of nanogrid was 65 nanometers. An extruded transparent polyester film (SAEHAN Corp. in Korea) having the thickness of 100 μm as a resin layer was pressed with the nickel stamper and heated at 150° C. to form grooves and protrusions corresponding to a mold of the stamper (using a nano imprinting instrument of NND Corp. in Korea). Subsequently, a solution (made by Advanced Nano Products Corp. in Korea) where silver nano particles as the conductive filling material were dispersed and stabilized in ethanol selectively filled the grooves formed on the polyester film using a knife coating process (stainless comma knife), and is then dried for 30 minutes at 120° C. Subsequently, a protective film was formed using a transparent acryl-based resin to manufacture the nanogrid polarizer.

### Example 2

A polarizer was manufactured according to the procedure shown in FIG. 6. Specifically, a transparent photocurable liquid molding urethane acrylate resin (SK-CYTECH Corp. in Korea) was applied on a transparent polyester film (A4400 of TOYOBO CO. LTD in Japan) having the thickness of 100 μm as a substrate to form a photocurable resin layer. Subsequently, after the photocurable resin layer was pressed with the nickel stamper as shown in example 1, ultraviolet rays were radiated on the resin layer for 20 seconds to cure the resin layer, and the stamper was separated to form grooves and protrusions on the photocurable resin layer. Subsequently, aluminum is sputtered at an inclined side angle of 80° and at the rate of 0.2 nm/seconds to be deposited at the thickness of 150 nm (ULVAC Inc. in Japan) so that aluminum is selectively filled only on the protrusions of the resin layer. Then, a protective film was formed to manufacture the nanogrid polarizer.

### Comparative Example 1

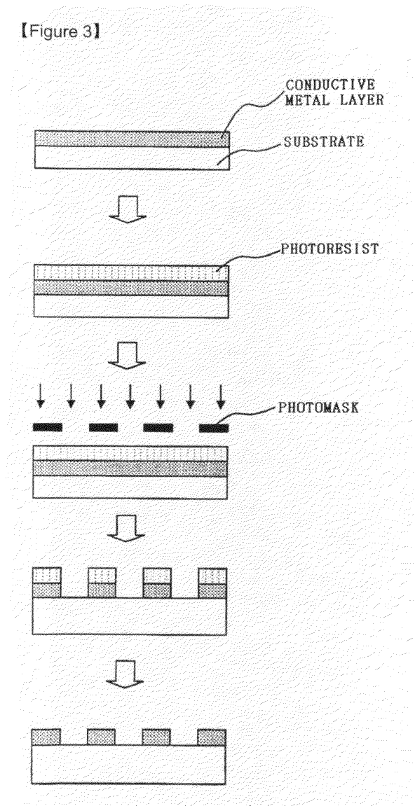

A polarizer was manufactured according to the procedure shown in FIG. 3. Specifically, aluminum was deposited on a quartz substrate. In this connection, a photoresist was applied using a coating process, and exposure was selectively conducted using a photomask. Subsequently, an aluminum layer corresponding in position to an exposed portion of the photoresist was removed using an etching process, and washing and rinsing were conducted to manufacture the nanogrid polarizer.

### Comparative Example 2

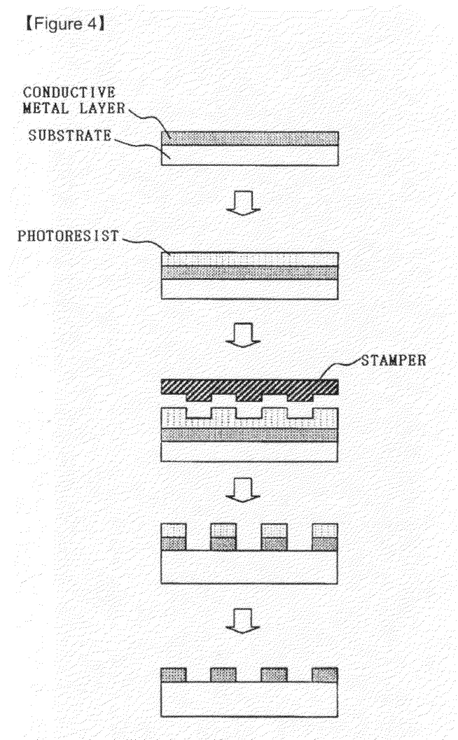

A polarizer was manufactured according to the procedure shown in FIG. 4. Specifically, the procedure of comparative example 1 was repeated to manufacture the nanogrid polarizer except that exposure was conducted after a photoresist was pressed using a stamper instead of an exposure process using a photomask.

### INDUSTRIAL APPLICABILITY

In comparison with a conventional method of patterning a conductive layer which includes patterning a photoresist layer and an etching process, a method of patterning a conductive layer according to the present invention is advantageous in that cost is low, a simple process is assured, efficiency of use of a raw material is maximized, and pollution caused by the etching is prevented, thus cleanness of the process is assured. Furthermore, since a stamper that is manufactured so as to have a large area using a stereolithography process is used to pattern the conductive layer, the conductive layer can be efficiently patterned with respect to the large area. Accordingly, the method of the present invention is useful to manufacture the nanogrid polarizer having the large area.

Although the preferred embodiments of the present invention have been disclosed for illustrative purposes, those skilled in the art will appreciate that various modifications, additions and substitutions are possible, without departing from the scope and spirit of the present invention as disclosed in the accompanying claims.

1. A method of patterning a conductive layer comprising:
(a) patterning a resin layer to form grooves and protrusions; and
(b) applying a conductive filling material on the resin layer so as to form a pattern using stereoscopic shapes of the grooves and the protrusions on the patterned resin layer.

2.-3. (canceled)

4. The method according to claim 1, wherein the conductive filling material is selectively applied on only the grooves, only the protrusions, or on a portion of the grooves and a portion of the protrusions of the resin layer in step (b).

5. The method according to claim 1, wherein step (b) is conducted using a selective wet or dry coating process.

6. The method according to claim 5, wherein the selective dry coating process of step (b) is an inclined sputtering process.

7. The method according to claim 1, wherein the resin layer is formed of an optically transparent organic material.

8. The method according to claim 1, wherein the resin layer is formed on a substrate that is formed of a material selected from the group consisting of an inorganic material and an organic material, and the resin layer is formed of a curable liquid resin.

9. The method according to claim 1, further comprising:
(c) forming a protective layer on the resin layer and the conductive layer after step (b).

10. The method according to claim 1, wherein the conductive filling material is selected from the group consisting of metal, a mixture of the metal and an organic material, and a conductive organic substance

11. A method of manufacturing a polarizer using the method according to claim 1.

12.-13. (canceled)

14. A method of manufacturing a polarizer using the method according to claim 4.

15. A method of manufacturing a polarizer using the method according to claim 5.

16. A method of manufacturing a polarizer using the method according to claim 6.

17.-20. (canceled)
